(19) United States
(12) Patent Application Publication
(10) Pub. No.: US 2025/0162081 A1
(43) Pub. Date: May 22, 2025

(54) LASER PROCESSING APPARATUS, LASER PROCESSING METHOD AND SUBSTRATE DICING METHOD USING THE SAME

(71) Applicant: Samsung Electronics Co., Ltd., Suwon-si (KR)

(72) Inventors: Dongju PARK, Suwon-si (KR); Jaeheung LEE, Suwon-si (KR); Namtae HEO, Suwon-si (KR)

(73) Assignee: Samsung Electronics Co., Ltd., Suwon-si (KR)

(21) Appl. No.: 18/906,657

(22) Filed: Oct. 4, 2024

(30) Foreign Application Priority Data
Nov. 22, 2023 (KR) 10-2023-0163629

(51) Int. Cl. B23K 26/38; B23K 26/0622

(52) U.S. Cl. CPC B23K 26/38; B23K 26/0622

(57) ABSTRACT

A laser processing apparatus includes a stage configured to support a substrate that is a processing object, a laser irradiation portion configured to focus a laser beam inside the substrate to form a laser damage layer inside the substrate along a cutting line, and a thermoreflectance measurement portion configured to irradiate a detection light onto an adjacent region near a region where the laser beam is focused and detect light reflected from the adjacent region to determine a location of splash defect in the adjacent region generated by the laser beam.

### PRIORITY STATEMENT

This application claims priority under 35 U.S.C. § 119 to Korean Patent Application No. 10-2023-0163629, filed on Nov. 22, 2023 in the Korean Intellectual Property Office (KIPO), the contents of which are herein incorporated by reference in their entirety.

### BACKGROUND

### 1. Field

Example embodiments relate to a laser processing apparatus, a laser processing method, and a substrate dicing method using the same. More particularly, example embodiments relate to a laser processing apparatus configured to irradiate a laser light inside a substrate to cut the substrate, a laser processing method using the same, and a substrate dicing method using the same.

### 2. Description of the Related Art

In a GAL (Grinding After Laser) process, when a laser beam is irradiated inside a wafer to form a stealth dicing layer, splash damage may occur due to laser light scattering that damages circuit patterns in adjacent die regions. In order to measure such splash defects, a metal film as a sample may be coated on a surface opposite to an incident surface of the wafer and traces of scattering damage generated on the metal film during laser processing may be indirectly detected. However, reliability may be deteriorated due to sample deviation, and since splash damage cannot be directly detected during actual processing, there is a problem that a long-term verification period is required to secure test yield. Therefore, alternatives are being pursued.

### SUMMARY

Example embodiments provide a laser processing apparatus that is configured to detect splash defects in real time.

Example embodiments provide a laser processing method using the laser processing apparatus.

Example embodiments provide a method of dicing a substrate using the laser processing method.

According to example embodiments, a laser processing apparatus configured to laser process a substrate includes a stage configured to support the substrate; a laser irradiation portion configured to focus a laser beam inside the substrate such that a laser damage layer is formed inside the substrate along a cutting line; and a thermoreflectance measurement portion configured to irradiate a detection light onto an adjacent region and to detect light reflected from the adjacent region to determine a location of splash defect in the adjacent region generated by the laser beam, wherein the adjacent region is adjacent to a region where the laser beam is focused.

According to example embodiments, a laser processing apparatus configured to laser process a substrate includes a stage configured to support the substrate; a laser irradiation portion configured to focus a laser beam inside the substrate such that a laser damage layer is formed inside the substrate along a cutting line; an illumination portion configured to irradiate a detection light to an adjacent region, wherein the adjacent region is adjacent to a region where the laser beam is focused; a light detector configured to detect light reflected from the adjacent region; and processing circuitry configured to determine a reflectance change rate from an intensity of the light detected by the light detector and to determine a location of splash defect generated by the laser beam.

According to example embodiments, a laser processing apparatus configured to laser process a substrate including a base substrate having a first surface and a second surface opposite to the first surface and a circuit layer formed on the first surface of the base substrate includes a stage configured to support the substrate such that the first surface faces the stage; a laser irradiation portion configured to focus a laser beam inside the substrate such that a laser damage layer is formed inside the substrate along a cutting line; and a thermoreflectance measurement portion configured to irradiate a detection light to an adjacent region and to detect light reflected from the circuit layer in the adjacent region and to determine a location of splash defect in the adjacent region generated by the laser beam, wherein the adjacent region is adjacent to a region where the laser beam is focused, and wherein the thermoreflectance measurement portion is configured to irradiate the detection light such that the detection light is incident to the circuit layer through the second surface of the base substrate.

According to example embodiments, a laser processing apparatus may include a laser irradiation portion configured to focus a laser beam inside a substrate along a cutting line such that a laser damage layer is formed inside the substrate, and a thermoreflectance measurement portion configured to irradiate a detection light onto an adjacent region adjacent the region where the laser beam is focused and to detect light reflected from the adjacent region to determine a reflectance change rate. The thermoreflectance measurement portion may measure the reflectance change rate from an intensity of the detected light to determine a location of splash defect in the adjacent region.

When the laser beam is scanned along the cutting line of the substrate by the laser irradiation portion, the thermoreflectance measurement portion may measure the splash damage portion due to laser light scattering in real time.

Accordingly, the laser light scattering damage may be measured in real time without a separate indirect measurement, e.g., using a metal sample such as tin. Thus, test reliability for splash damage may be improved and test yield may be improved.

### BRIEF DESCRIPTION OF THE DRAWINGS

Example embodiments will be more clearly understood from the following detailed description taken in conjunction with the accompanying drawings. FIGS. 1 to 16 represent non-limiting, example embodiments as described herein.

FIG. 1 is a perspective view illustrating a laser processing apparatus in accordance with some example embodiments.

FIG. 2 is a block diagram illustrating the laser processing apparatus of FIG. 1.

FIG. 3 is a block diagram illustrating a controller for controlling a laser light source, a detection light illumination portion, and a stage driving portion of FIG. 1.

FIG. 4 is a graph illustrating timing control of the laser processing apparatus of FIG. 1.

FIG. 5 is a plan view illustrating a cutting line of a wafer along which a laser beam is scanned.

FIG. 6 is a perspective view illustrating a detection light incident along with the laser beam of FIG. 5 and a reflected light of the detection light.

FIG. 7 is a plan view illustrating damaged portions of a circuit layer due to laser splash during scanning of a laser beam.

FIG. 8 is a graph illustrating an intensity of light in each pixel detected by a light detection portion.

FIG. 9 is a view illustrating a change in thermoreflectance due to temperature change.

FIG. 10 is a flow chart illustrating a laser processing method in accordance with some example embodiments.

FIG. 11 is a flow chart illustrating a substrate dicing method in accordance with example embodiments.

FIGS. 12 to 16 are views illustrating a substrate dicing method in accordance with example embodiments.

### DETAILED DESCRIPTION OF EXAMPLE EMBODIMENTS

Hereinafter, example embodiments will be explained in detail with reference to the accompanying drawings, wherein like reference numerals refer to like elements throughout.

It will be understood that, although the terms “first,” “second,” etc. may be used herein to describe various elements. These terms are only used to distinguish one element from another, and these elements should not be otherwise limited by these terms.

Additionally, whenever a range of values is enumerated, the range includes all values within the range as if recorded explicitly clearly, and may further include the boundaries of the range. Accordingly, the range of “X” to “Y” includes all values between X and Y, including X and Y. Further, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometric term.

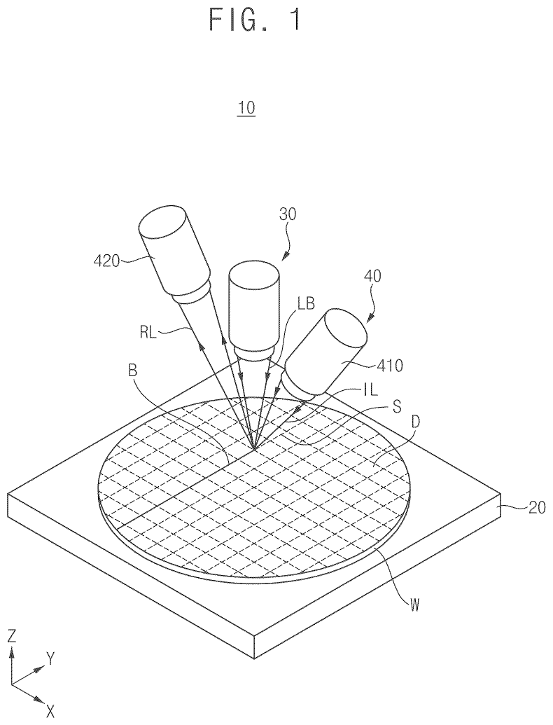

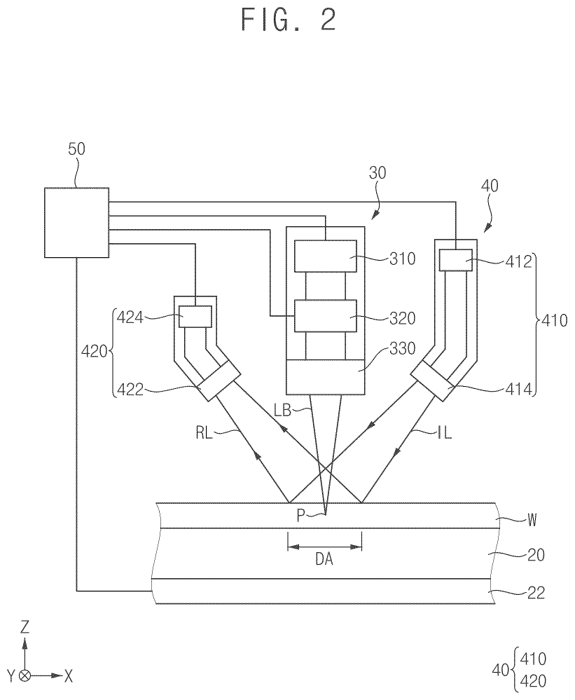

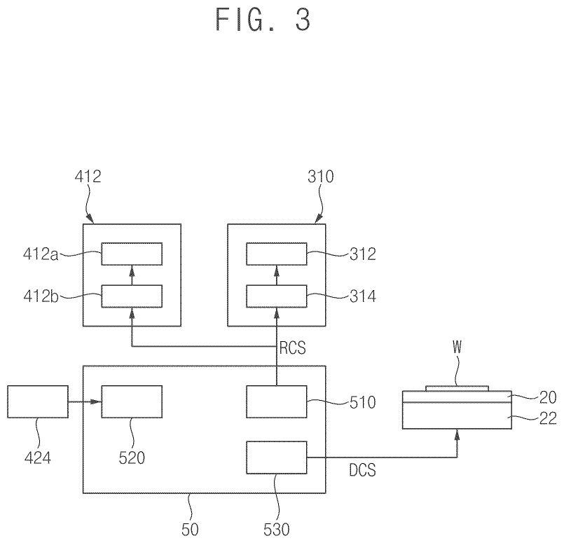

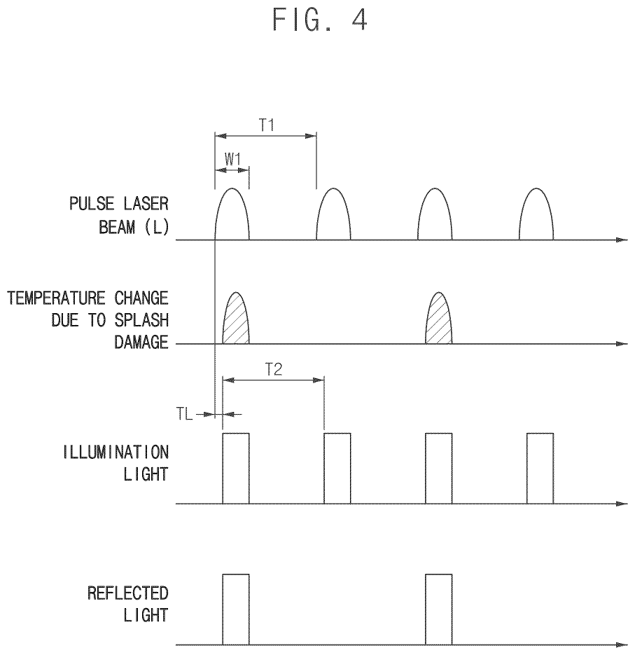

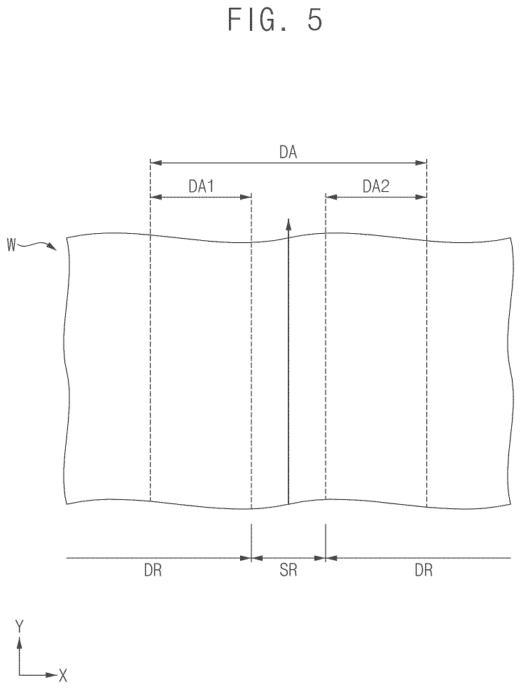

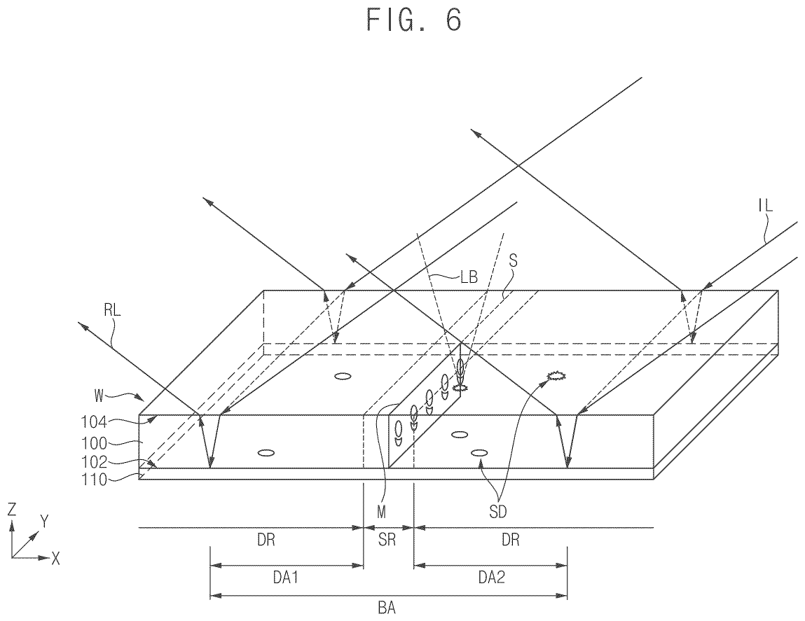

FIG. 1 is a perspective view illustrating a laser processing apparatus in accordance with some example embodiments. FIG. 2 is a block diagram illustrating the laser processing apparatus of FIG. 1. FIG. 3 is a block diagram illustrating a controller for controlling a laser light source, a detection light illumination portion, and a stage driving portion of FIG. 1. FIG. 4 is a graph illustrating timing control of the laser processing apparatus of FIG. 1. FIG. 5 is a plan view illustrating a cutting line of a wafer along which a laser beam is scanned. FIG. 6 is a perspective view illustrating a detection light incident along with the laser beam of FIG. 5 and a reflected light of the detection light.

Referring to FIGS. 1 to 6, a laser processing apparatus 10 according to at least some embodiments includes a stage 20, a laser irradiation portion 30, and a thermoreflectance measurement portion 40. In addition, the laser processing apparatus 10 may be connected to and/or include processing circuitry such as hardware, software, and/or a combination of hardware and software configured to control the operations of the laser processing apparatus. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. For example, the laser processing apparatus 10 may further include a controller 50 connected to the stage 20, the laser irradiation portion 30, and/or the thermoreflectance measurement portion 40 configured to control the operations of the connected ones of the stage 20, the laser irradiation portion 30, and/or the thermoreflectance measurement portion 40. In at least some embodiments, the controller 50 may be provided separate from the stage 20, the laser irradiation portion 30, and/or the thermoreflectance measurement portion 40 (as illustrated) and/or may be included in and/or distributed throughout at least one of the stage 20, the laser irradiation portion 30, and/or the thermoreflectance measurement portion 40.

In example embodiments, the laser processing apparatus 10 may irradiate a laser beam LB within a substrate W (such as a wafer) to apply a local high density energy into a focal point P to thereby form a stealth dicing layer as a modified region. The laser processing apparatus 10 may scan the laser beam LB along a cutting line on the substrate W. Accordingly, laser damage layers, which are modified regions, may be formed within the substrate W along the cutting line. The laser damage layer formed along the cutting line, that is, a scribe lane region SR, may be a cutting starting region.

The laser processing apparatus 10 may further include a driving portion configured to move the laser beam LB relative to the substrate W. For example, the driving portion may include a stage driver 22 configured to move the stage 20 in X, Y, and Z directions.

In some embodiments, the stage 20 may be a table that is movable in at least one of the X, Y, and/or Z direction and supports the substrate W. The stage 20 may be installed to be movable in X direction and Y direction on the stage driver 22. The stage driver 22 may include a stage drive mechanism configured to move the stage 20, and the stage driver 22 may move the stage 20 in X and Y directions according to a drive control signal (DCS) of a drive controller 530. A moving speed of the stage 20 may be adjustable.

In addition, the driving portion may further include a laser head driver (not illustrated) configured to move the laser irradiation portion 30 in X, Y, and Z directions. For example, the laser head driver may move an optical system of the laser irradiation portion 30 in X, Y, and Z directions. For example, the laser head driver may move the laser irradiation portion 30 in Z direction, and the stage driver 22 may move the wafer W in X and Y directions and may rotate the stage 20 around the center of the wafer W. In at least some embodiments, the driving portion includes, e.g., a motor, pneumatics, a gear train, and/or the like configured to move the stage 20 and/or the laser irradiation portion 30.

In some embodiments, the intensity and/or wavelength of the laser irradiation portion 30 may be selected based on the material and/or thickness of the substate W. For example, the substrate W may include a silicon wafer (Si Wafer), a silicon carbide wafer (SiC Wafer), a gallium arsenide wafer (GaAs Wafer), a silicon single crystal wafer (Si-Single Crystal Wafer) and/or the like; additionally, a thickness of the substrate W may be in a range of 50 μm (micrometers) to 850 μm; and the intensity and/or wavelength of the laser irradiation portion 30 selected accordingly.

As illustrated in FIG. 2, the laser irradiation portion 30 may include a laser light source 310 configured to generate a laser beam LB, a beam shaper 320 configured to change the laser beam LB into a desired shape, and a condenser lens 330 configured to concentrate the shaped beam LB inside the substrate W.

In particular, in at least some embodiments, the laser light source 310 may be a single light source configured to emit a laser beam. The laser beam may have a wavelength band having transparency to the substrate W, which is the object to be processed. The wavelength band may be, for example, within a wavelength range of 1,080 nm (nanometers) to 1,100 nm. The laser light source 310 may include a laser oscillator 312 configured to emit a pulsed laser beam and a laser oscillator controller configured to control a period of the pulsed laser beam. In at least some embodiments, an intensity of the irradiated pulse light may exhibit a Gaussian distribution.

The laser oscillator 312 may be configured to emit a pulse laser beam of a first period (T1) for a first cycle synchronized to a clock signal (RCS) generated by a reference clock oscillation controller 510 of the controller 50. For example, the reference clock oscillation controller 510 of the controller 50 may be configured to generate a clock signal (RCS) with a preset period (Tc), and the laser oscillator controller 314 may receive the clock signal (RCS) and may control the laser oscillator 312 to emit a pulse laser beam of the first period (T1) synchronized with the clock signal (RCS). At this time, the pulse laser beam may have a preset delay time with respect to the clock signal (RCS). For example, a delay time may occur between a rise of the clock signal (RCS) and a rise of the pulse laser beam. The laser beam LB may be a pulse laser beam having a pulse width W1 of 1 μm or less. However, it may not be limited thereto, and the laser light source 310 may emit a continuous wave laser beam depending on the type of processing operation.

The laser light source 310 may include a solid medium for passing the laser beam. The properties of the laser beam may vary depending on the solid medium. For example, the solid medium may include ytterbium yttrium aluminum garnet compound (Yb: YAG), neodymium yttrium aluminum garnet compound (Nd: YAG), neodymium yttrium orthovanadate compound (Nd: YVO4), aluminum gallium arsenide compound (AlGaAS), aluminum gallium indium compound (AlGaInP), gallium nitride compound (GaN), neodymium optical fiber (Nd-Fiber), sapphire, etc.

The beam shaper 320 may be configured to adjust the incident pulse laser beam into a pulse laser beam having a desired shape. For example, the beam shaper 320 may be a beam expander configured to expand a beam diameter by a constant magnification. The beam expander may expand the diameter of the collimated input beam and emit a collimated output beam having a larger diameter. Alternatively, the beam shaper 320 may include an optical element such as a homogenizer that uniformizes a light intensity distribution of the beam cross-section. Additionally, the beam shaper 320 may include an element that makes the beam cross-section circular or an optical element that circularly polarizes the beam.

The condenser lens 330 may be configured to focus the laser beam LB that has passed through the beam shaper 320 into a spot P. The condenser lens 330 may be provided, for example, on an optical path of the laser beam and may include a single lens optical system having a numerical aperture NA of at least 0.6. For example, the condenser lens 330 may include a single lens optical system in which a plurality of lenses are sequentially arranged.

The spot P may be a local position at which the laser beam LB is focused. When the substrate W is a silicon wafer, for example, the spot P may be provided between a lower (e.g., a first surface 102) and an upper surface (e.g., a second surface 104) in a scribe lane region SR of the silicon wafer such that a plurality of die regions D (e.g., arranged in a matrix shape) may be divided by cutting the scribe lane regions SR.

The driving portion of the laser processing apparatus 10 may move the laser beam LB in at least one of a first horizontal direction (X direction) or a second horizontal direction (Y direction) with respect to (or relative to) the substrate W to scan a cutting line on the substrate W with the laser beam LB. For example, the stage 20 may be moved in one direction by the stage driver 22 at a predetermined (or otherwise determined) scanning speed. The scanning speed of the laser beam LB may be determined by the moving speed of the stage 20. According to at least some embodiments, the scanning speed of the laser beam LB may be in a range of 300 millimeters per second (mm/s) to 2,000 mm/s. The pulse laser beam LB may be sequentially irradiated along the scribe lane region SR at intervals of 5 micrometers (μm) to 20 μm, and laser damage layers M may be intermittently formed inside the substrate W.

In some example embodiments, the thermoreflectance measurement portion 40 may measure a laser splash damage that occurs when the laser beam LB is irradiated onto the substrate W. For example, thermoreflectance measurement portion 40 may be configured to irradiate a detection light IL to an adjacent region DA near the region SR where the laser beam LB is focused; to detect light RL reflected from the adjacent region DA; and to determine a location of the laser splash defect within the substrate W generated by the laser beam LB. The thermoreflectance measurement portion 40 may, for example, include an illumination portion 410 and a light detector 420. The thermoreflectance measurement portion 40 may further include (and/or be connected to) a signal processor 520.

In particular, the illumination portion 410 may be configured to irradiate the detection light IL to the adjacent region DA near the region SR where the laser beam LB is focused. In at least some embodiments, the illumination portion 410 may include an illumination light source 412 and a converging lens 414. The illumination light source 412 may be configured to generate and/or irradiate the detection light IL to the adjacent region DA surrounding the position P on which the laser beam LB is focused. The detection light IL may have, in at least some embodiments, an infrared wavelength band. The infrared wavelength band may be within a wavelength range of 1,000 nm to 1,400 nm. In at least some embodiments, the illumination light source 412 may include an illumination light oscillator 412a configured to emit a pulse illumination light and an illumination light oscillator controller 412b configured to control a period (e.g., length of pulse and/or timing between pulses) of the pulse illumination light.

As illustrated in FIGS. 3 and 4, the illumination light oscillator 412a may be configured to generate a pulse illumination light of a second period (T2) of a second cycle synchronized with the clock signal (RCS) generated by the reference clock oscillation controller 510 of the controller 50. The illumination light oscillator controller 412b may receive the clock signal (RCS) from the reference clock oscillation controller 510 and may control the illumination light oscillator 412a to emit the pulse illumination light of the second period (T2) synchronized with the clock signal (RCS). The second period T2 of the illumination light IL may be the same as the first period T1 of the laser beam LB. In at least some embodiments, the second period T2 of the illumination light IL may be in a range of 50 kHz to 200 kH. At this time, the pulse illumination light may have a predetermined (and/or otherwise determined) delay time (TL) with respect to the laser beam (LB). That is, a delay time (TL) may occur between a rise of the pulse laser beam (LB) and a rise of the pulse illumination light (IL). In at least some embodiments, the time delay (TL) of the pulsed illumination light (IL) may be within 5 μs. The pulse illumination light IL may have a pulse width equal to or smaller than the pulse width W1 of the laser beam LB.

The light detector 420 may detect an intensity of the light RL reflected from the adjacent region DA. The light detector 420 may include a light receiving lens 422 and a detection sensor 424. The reflected light RL may be concentrated to the detection sensor 424 through the light receiving lens 422. The detection sensor 424 may include an image sensor for detecting the intensity of the reflected light RL. The image sensor may include, for example, a CCD (Charge-Coupled Device) sensor, a CMOS (Complementary Metal Oxide Semiconductor) sensor, etc.

The driving portion may further include a measuring driver (not illustrated) configured to move the illumination portion 410 and the light detector 420 in X, Y, and Z directions. For example, the measuring driver may be configured to move the illumination portion 410 and the light detector 420 together with the laser irradiation portion 30 in X, Y, and Z directions. Alternatively, the measuring driver may move the illumination portion 410 and the light detector 420 in Z direction, and the stage driver 22 may move the wafer W in X and Y directions and may rotate the stage 20 around the center of the wafer W.

As illustrated in FIGS. 5 and 6, the adjacent region DA on the substrate W irradiated with the illumination light IL may be a region DA including the cutting region SR irradiated with the laser beam LB. The adjacent region DA may have a first irradiation region DA1 and a second irradiation region DA2 on both sides of the cutting region SR. The adjacent region DA may have a polygonal shape, a cylindrical shape, a circular shape, etc. For example, the adjacent region DA illuminated with the illumination light IL may have an area of less than 1 mm×1 mm. The width of the cutting region SR may be within a range of 40 μm to 200 μm. Each of widths of the first irradiation region DA1 and the second irradiation region DA2 may be within a range of 300 μm to 480 μm. The first irradiation region DA1 and the second irradiation region DA2 may include a portion of the die region DR adjacent to the cutting region SR where circuit patterns damaged by laser splash are most likely to be formed.

In example embodiments, the wafer W may include a base substrate 100 such as a silicon substrate having a first surface 102 and a second surface 104 opposite to the first surface 102, and a circuit layer 110 formed on the first surface 102 of the base substrate 100. Circuit patterns may be formed in the circuit layer 110 in the die region DR. The circuit patterns may include transistors, capacitors, diodes, etc. The circuit patterns may constitute circuit elements. The circuit element may include a plurality of memory devices. Examples of the memory devices include volatile semiconductor memory devices and non-volatile semiconductor memory devices.

The stage may be configured to support the wafer W such the circuit layer 110 faces the stage 20, and the laser beam LB may be focused into the base substrate 100 through the backside surface of the wafer W, that is, the second surface 104 of the base substrate 100. The illumination light IL as the detection light may be irradiated onto the second surface 104 of the base substrate 100. The illumination light IL may pass through the base substrate 100 and may be incident on the circuit layer 110, and the light RL reflected from the circuit layer 110 may be emitted from the second surface 104 of the base substrate 100 and then, may be received by the light detector 420.

When a modified region is formed inside the substrate W by the laser beam LB, a portion of the circuit layer 110 may be damaged due to laser light scattering (laser splash). At this time, the reflectance from the damaged portion may change, the light detector 420 may detect a change in the intensity of the reflected light RL due to the change in reflectance, and the signal processor 520 of the controller 50 may calculate the reflectance change rate from the intensity of the detected light to determine the location (and/or extent) of the damage.

Hereinafter, a method for calculating the reflectance change rate from the intensity of light detected by the light detector 420 and determining the location of the splash defect will be described.

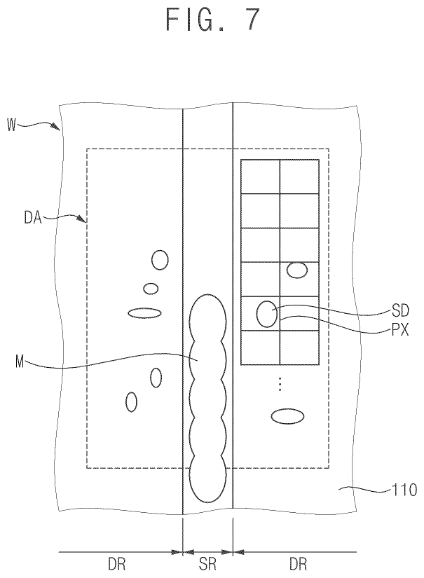

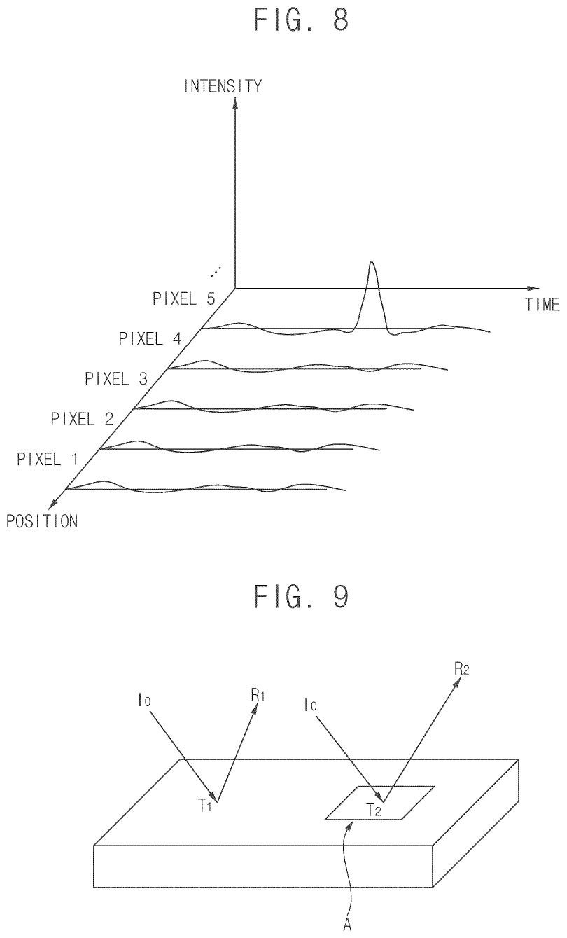

FIG. 7 is a plan view illustrating damaged portions of a circuit layer due to laser splash during scanning of a laser beam. FIG. 8 is a graph illustrating an intensity of light in each pixel detected by a light detection portion. FIG. 9 is a view illustrating a change in thermoreflectance due to temperature change.

Referring to FIGS. 7 to 9, when a laser beam LB is scanned along a cutting region SR of a substrate W, splash damage regions SD may be generated in portions of the circuit layer 110 due to the laser light scattering inside the substrate W. Therefore, to determine the location of the splash defect at the same time and/or after the laser beam LB is scanned along the cutting region SR, an illumination light IL may be irradiated onto an adjacent region DA1 and DA2 near the region SR where the laser beam LB is focused, and the light detector 420 may detect an intensity of light in each pixels corresponding to the adjacent region DA. The temperature change may occur rapidly at the point where splash damage (SD) occurs, and as illustrated in FIG. 8, the intensity of light at the pixel (Pixel 5) corresponding to the splash damage point may rapidly increase.

Each pixel PX may have a size corresponding to (or depending) on a size of the splash damage portion (SD). For example, the pixel may represent an area having a size of several micrometers. The number and size of the pixels may be determined depending on the magnification of the lenses used, the specifications of the sensor, etc.

As illustrated in FIG. 9, when temperature in a surface of a specific area A of an object changes (T1->T2), the reflectance of light reflected from the surface also changes. The amount of change in temperature and the rate of change in reflectance may be expressed by equation (1) below.

$$Δ T = {( \frac{1}{R} \frac{\partial R}{\partial T} )}^{- 1} \frac{Δ R}{R} = {k}^{- 1} \frac{Δ R}{R} \qquad Equation ( 1 )$$

Here, ΔT is the temperature change, ΔR/R is the reflectance change rate, and k is the thermoreflectance coefficient.

Accordingly, by measuring the amount of change in reflectance from the intensity of the reflected light RL, the temperature change in a specific area may be determined. For example, the signal processor 520 of the controller 50 may calculate the reflectance change rate from the intensity of the detected light to determine the position of the splash defect within the substrate W.

As mentioned above, the laser processing apparatus 10 may include the laser irradiation portion 30 configured to focus the laser beam LB inside the substrate W along the cutting line of the substrate W, and the thermoreflectance measurement portion 40 configured to irradiate the detection light IR to the adjacent region DA1, DA2 surrounding the region on which the laser beam LB is focused and to detect the light RL reflected from the adjacent region to calculate the reflectance change rate. Thereby, the thermoreflectance measurement portion 40 may determine the location of the splash defect within the substrate W by measuring the amount of change in reflectance from the intensity of the reflected light RL.

When the laser beam LB is scanned along the cutting line SR of the substrate W by the laser irradiation portion 30, the thermoreflectance measurement portion 40 may measure the splash damage portion SD due to laser light scattering in real time.

Accordingly, the laser light scattering damage may be measured in real time without a separate indirect measurement using a metal sample such as tin. Thus, test reliability for splash damage may also be improved and test yield may be improved.

Hereinafter a laser processing method using the laser processing apparatus of FIG. 1 will be described.

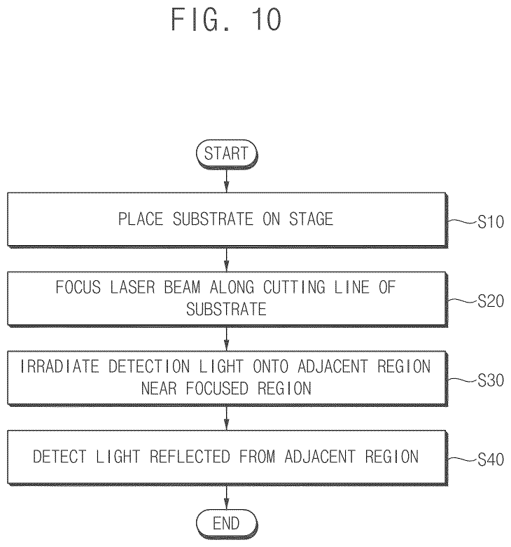

FIG. 10 is a flow chart illustrating a laser processing method in accordance with some example embodiments.

Referring to FIGS. 1 to 10, first, a substrate W, which is a processing object, may be supported on a stage 20 (S10), and a laser beam LB may be focused along a cutting line SR of the substrate W.

In some example embodiments, after placing the substrate W on the stage 20 of FIG. 1, a laser beam may first be generated by a laser light source 310 as a single light source, may be converted into a laser beam of a desired shape by a beam shaper 320, and may be condensed into a spot P within the substrate W through a condenser lens 330.

For example, the substrate W includes a base substrate 100 such as a silicon substrate having a first surface 102 and a second surface 104 opposite to the first surface 102, and a circuit layer 110 formed on the first surface 102 of the base substrate 100. Circuit patterns may be formed in the circuit layer 110 in a die region DR. The substrate W may be supported on the stage 20 such that the circuit layer 110 faces the stage 20.

The laser beam irradiated onto the substrate W may have a wavelength band having transparency and/or partially transparency to the substrate W, which is the processing object. In at least some embodiments, the wavelength band may be within a wavelength range of 1,080 nm to 1,100 nm. The laser light source 310 may emit a pulse laser beam of a first period (T1) synchronized with a clock signal (RCS). The first period (T1) of the pulsed laser beam may be in a range of 50 kHz to 200 kH. The laser beam LB may be a pulse laser beam having a pulse width W1 of 1 μm or less. However, it may not be limited to thereto, and the laser light source 310 may emit a continuous wave laser beam depending on the type of processing operation.

The focus P of the laser beam LB may be located inside the substrate W, and the laser beam LB may be relatively moved in a second horizontal direction (Y direction) along the cutting line S. The scanning speed of the laser beam L may be in a range of 300 mm/s to 2,000 mm/s.

Accordingly, as illustrated in FIG. 6, a laser damage layer M, which is a modified region, may be formed inside the substrate W. The laser damage layers M formed along the cutting lines S, that is, scribe lane regions, may serve as a cutting starting region. The laser damage layer M may be formed continuously or intermittently along the cutting line.

For example, when the laser beam LB is converged within the substrate W, the laser beam may be absorbed in the spot P to be melted, expanded, contracted and solidified. In the contraction stages, the left and right regions of the spot P may be contracted earlier so that a crack begins to appear in the middle region of the spot P. When the contraction stage is completed, the crack may grow in upward and downward directions to form a vertical crack. The laser light L may be irradiated intermittently while moving the laser light L relative to the substrate 100 (e.g., along the cutting lines S through the above process) to from a stealth dicing line B within the substrate 100 along X direction as illustrated in FIG. 6.

In at least one embodiment, then, a detection light IR may be irradiated to an adjacent region DA1, DA2 near the focused region P (S30), and a light RL reflected from the adjacent region DA1, DA2 may be detected (S40).

Alternatively, in some example embodiments, when the laser beam LB is focused inside the substrate W along the cutting line SR of the substrate W by the laser irradiation portion 30, the illumination portion 410 may irradiate the detection light IL on the adjacent region DA near the area SR where the laser beam LB is focused.

The detection light IL may have an infrared wavelength band. The infrared wavelength band may be within a wavelength range of 1,000 nm to 1,400 nm. The illumination portion 410 may be controlled to emit a pulse illumination light of a second period (T2) synchronized with the clock signal (RCS). The second period T2 of the illumination light IL may be the same as the first period T1 of the laser beam LB. The second period T2 of the illumination light IL may be in a range of 50 kHz to 200 kH. At this time, the pulse illumination light may have a predetermined delay time TL with respect to the laser beam LB. That is, a delay time TL may occur between a rise of the pulse laser beam LB and a rise of the pulse illumination light IL. The time delay TL of the pulsed illumination light IL may be within 5 μs. The pulse illumination light IL may have a pulse width equal to or smaller than the pulse width W1 of the laser beam LB.

The adjacent region DA on the substrate W irradiated with the illumination light IL may be a region DA including the cutting region SR irradiated with the laser beam LB. The adjacent region DA may have a first irradiation region DA1 and a second irradiation region DA2 on both sides of the cutting region SR. The adjacent region DA may have a polygonal shape, cylindrical shape, a circular shape, etc. For example, the adjacent region DA illuminated by the illumination light IL may have an area of less than 1 mm×1 mm. The width of the cutting region SR may be within a range of 40 μm to 200 μm. Each of widths of the first irradiation region DA1 and the second irradiation region DA2 may be within a range of 300 μm to 480 μm. The first irradiation region DA1 and the second irradiation region DA2 may include a portion of the die region DR adjacent to the cutting region SR where circuit patterns damaged by laser splash are formed.

A light detector 420 may detect an intensity of the light RL reflected from the adjacent region DA. The light detector 420 may include an image sensor for detecting the intensity of the reflected light RL. The image sensor may include a CCD (Charge-Coupled Device) sensor, a CMOS (Complementary Metal Oxide Semiconductor) sensor, etc.

The laser beam LB may be focused inside the base substrate 100 through the backside surface of the wafer W, that is, the second surface 104 of the base substrate 100. The illumination light IL as the detection light may be radiated onto the second surface 104 of the base substrate 100. The illumination light IL may pass through the base substrate 100 and may be incident on the circuit layer 110, and the light RL reflected from the circuit layer 110 may be emitted from the second surface 104 of the base substrate 100 and then, may be received by the light detector 420.

Then, a signal processer 520 of a controller 50 may receive a signal about the intensity of the detected light from the light detector 420, calculate a reflectance change rate based on this, and may determine a location of the splash defect in the substrate W.

When the laser beam LB is scanned along the cutting line SR of the substrate W, a portion of the circuit layer 110 may be damaged due to light scattering of the laser beam LB. A rapid change in temperature may occur in the damaged portion SD caused by laser splash inside the substrate W. The light detector 420 may detect the intensity of the reflected light RL, and the signal processer 520 nay measure the amount of change in reflectance from the intensity of the reflected light RL, to determine the location of the damaged portion.

Hereinafter, a method of dicing a substrate using the above-described laser processing apparatus and laser processing method will be described.

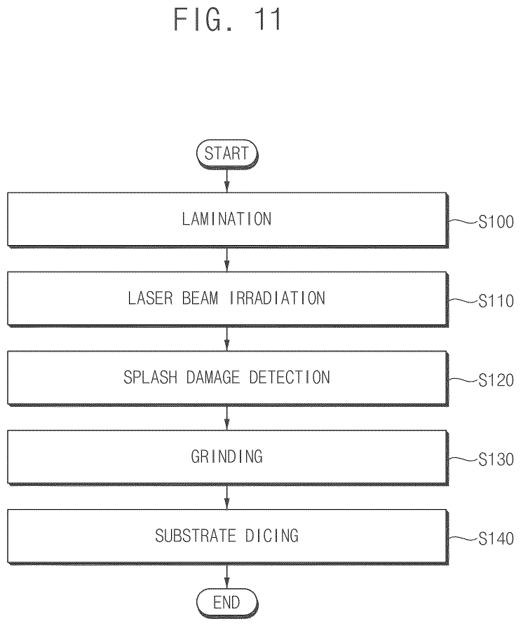

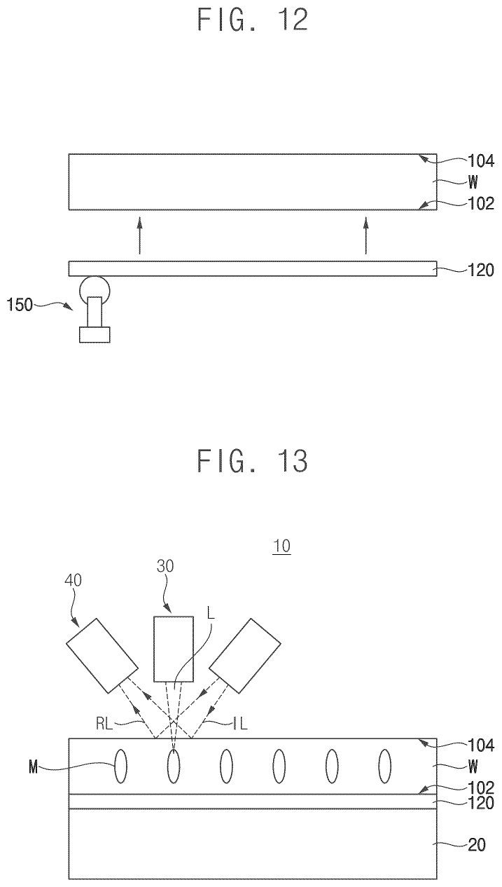

FIG. 11 is a flow chart illustrating a substrate dicing method in accordance with example embodiments. FIGS. 12 to 16 are views illustrating a substrate dicing method in accordance with example embodiments.

Referring to FIGS. 11 to 16, first, a protective tape 120 for protecting circuit elements may be adhered onto a first surface (active surface) 102 of a substrate W (lamination) (S100), and then, a laser beam LB may be irradiated on a second surface 144 opposite to the first surface 102 of the substrate W along a cutting line to form laser damage layers M (S110). When the laser beam LB is scanned along the cutting line SR of the substrate W, a damaged portion generated by laser light scattering inside the substrate W may be detected (S120).

As illustrated in FIG. 12, in example embodiments, the protective tape 120 may be attached to the first surface 102 of the substrate W using a tape attachment apparatus 150. The protective tape 120 may be formed on a circuit layer 110 on the first surface 102 of the substrate W to protect the circuit elements.

As illustrated in FIG. 13, the laser light LB may be irradiated into the substrate 100 while locating a spot P within the substrate W, to form optically damaged portions (laser damage layers) M within the substrate W by multiphoton absorption. The laser light LB may be moved relatively along the cutting line S to form the laser damage layers M as the modified regions within the substrate 100. The laser damage layer M formed along the cutting line S, that is, a scribe lane region may be a cutting start region.

Then, when the laser beam LB is scanned along the cutting line SR of the substrate W, an adjacent region DA surrounding the spot generated by the laser beam LB may be measured using a thermoreflectance measurement portion 40 to detect a location of splash defect within the substrate W.

An illumination portion 410 may irradiate an illumination light IL as a detection light onto the second surface 104 of the substrate W, and The illumination light IL may pass through the base substrate 100 and may be incident on the circuit layer 110, and the light RL reflected from the circuit layer 110 may be emitted from the second surface 104 of the based substrate 100 and then, may be received by the light detector 420. A light detector 420 may detect an intensity of the reflected light RL, and a signal processor 520 of a controller 50 may calculate a reflectance change rate from the intensity of the detected light to determine the location of the splash defect.

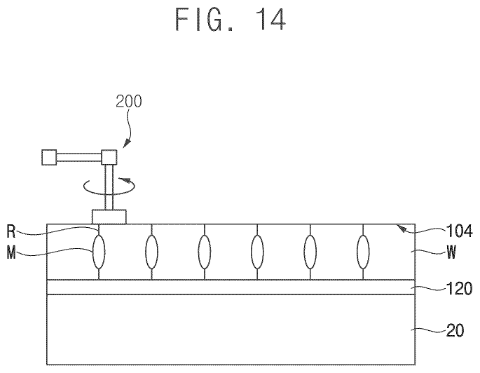

As illustrated in FIG. 14, the second surface 104 of the substrate W on which the laser damage layer M is formed may be polished using a grinding apparatus 200 (S130). By grinding the second surface 104 of the substrate W, the thickness of the substrate W may be reduced to a desired thickness. At this time, during the grinding process, the laser damage layer M may function as a dicing start region to form a vertical crack R therefrom. Therefore, the grinding may be controlled based on the determined locations of the splash defect, such that, e.g., the rate of polishing over said splash defects is reduced to prevent and/or mitigate the formation of undesired vertical cracks from forming from said defects. Similarly, if an area includes splash defects which are too large and/or concentrated, the area may be identified for, e.g., additional processing and/or removal. Additionally, in at least some embodiments, the intensity and/or speed of the laser beam LB may be controlled based on the formation of splash defects. For example, when a determination that the rate of formation for the splash defects is above a threshold value, in at least some embodiments, the intensity of the laser beam may be decreased and/or the speed of the laser beam across the substrate W may be increased.

After performing the grinding process, the protective tape 120 may be removed from the substrate W.

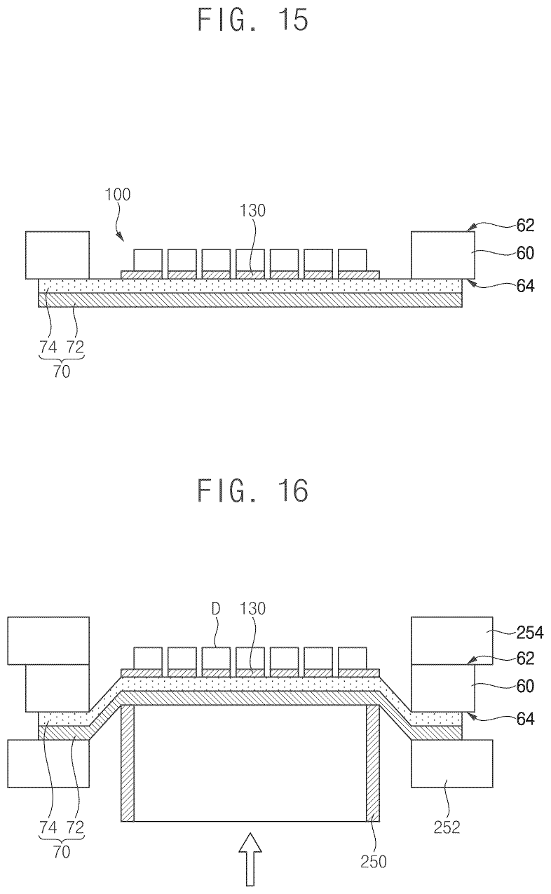

As illustrated in FIGS. 15 and 16, the substrate W may then be diced into individual chips (S140).

In example embodiments, a dicing tape 70 may be adhered on a lower surface 62 of a ring frame 60. The dicing tape 70 may be attached to the ring frame 60 by an adhesive force of an adhesive layer 74. The substrate W on which a plurality of semiconductor chips are formed may be attached to an adhesive film 130 and the substrate W may be attached to the dicing tape 70. The adhesive film 130 may be spaced apart from an inner surface of the ring frame 60. The adhesive film 130 may include a die attach film (DAF) as an organic adhesive.

Then, the dicing tape 70 may be expanded to separate the substrate W into a plurality of semiconductor chips D.

In example embodiments, after fixing an attachment region of the ring frame 60 and the dicing tape 70 between a fixing member 252 and a stage 254, a cylindrical pressing member 250 may be raised to expand the dicing tape 70. Accordingly, the divided chips on the dicing tape 70 may be spaced apart from each other in a radial direction. At this time, the adhesive film 130 may also be separated.

Then, a pickup process may be performed to pick up the individually separated semiconductor chips (D). Accordingly, the semiconductor chip D to which the adhesive film 130 is attached may be attached to a package substrate or another semiconductor chip to form a semiconductor package.

The semiconductor package formed by the above-described laser processing apparatus may include semiconductor devices such as logic devices or memory devices. For example, the semiconductor package may include logic devices such as central processing units (CPUs), main processing units (MPUs), or application processors (APs), or the like, and volatile memory devices such as DRAM devices, SRAM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A laser processing apparatus configured to laser process a substrate, the laser processing apparatus comprising:
a stage configured to support the substrate;
a laser irradiation portion configured to focus a laser beam inside the substrate such that a laser damage layer is formed inside the substrate along a cutting line; and
a thermoreflectance measurement portion configured to irradiate a detection light onto an adjacent region and to detect light reflected from the adjacent region to determine a location of splash defect in the adjacent region generated by the laser beam, wherein the adjacent region is adjacent to a region where the laser beam is focused.

2. The laser processing apparatus of claim 1, wherein the thermoreflectance measurement portion is configured such that the detection light has a wavelength within an infrared wavelength band.

3. The laser processing apparatus of claim 1, wherein
the laser irradiation portion is configured such that the laser beam includes a first pulse light of a first cycle, and
the thermoreflectance measurement portion is configured such that the detection light includes a second pulse light of a second cycle.

4. The laser processing apparatus of claim 3, wherein the laser processing apparatus is configured such that the second cycle is the same as the first cycle.

5. The laser processing apparatus of claim 4, wherein the laser processing apparatus is configured such that the second cycle is within a range of 50 kilohertz (kHz) to 200 kHz.

6. The laser processing apparatus of claim 4, wherein the laser processing apparatus is configured such that the second pulse light has a time delay with respect to the first pulse light, and the time delay is within a range of 5 microseconds (μs).

7. The laser processing apparatus of claim 1, wherein the thermoreflectance measurement portion includes:
an illumination portion configured to irradiate the detection light on the adjacent region; and
a light detector configured to detect an intensity of light reflected from the adjacent region, and
wherein the laser processing apparatus further includes a processing circuitry configured to determine a reflectance change rate from the intensity of the detected light and to determine the location of the splash defect.

8. The laser processing apparatus of claim 7, wherein the light detector includes an image sensor configured to detect the intensity of the reflected light.

9. The laser processing apparatus of claim 1, wherein the substrate includes a base substrate having a first surface and a second surface opposite to the first surface and a circuit layer formed on the first surface of the base substrate,
wherein the laser irradiation portion is configured such that the laser beam is irradiated onto the second surface of the base substrate, and
wherein the thermoreflectance measurement portion is configured such that the detection light is irradiated onto the second surface of the base substrate.

10. The laser processing apparatus of claim 1, further comprising:
a driving portion configured to move the laser beam in a horizontal direction relative to the substrate.

11. A laser processing apparatus configured to laser process a substrate, the laser processing apparatus comprising;
a stage configured to support the substrate;
a laser irradiation portion configured to focus a laser beam inside the substrate such that a laser damage layer is formed inside the substrate along a cutting line;
an illumination portion configured to irradiate a detection light to an adjacent region, wherein the adjacent region is adjacent to a region where the laser beam is focused;
a light detector configured to detect light reflected from the adjacent region; and
processing circuitry configured to determine a reflectance change rate from an intensity of the light detected by the light detector and to determine a location of splash defect generated by the laser beam.

12. The laser processing apparatus of claim 11, wherein the illumination portion is configured such that the detection light has a wavelength within an infrared wavelength band.

13. The laser processing apparatus of claim 11, wherein the laser irradiation portion is configured such that the laser beam includes a first pulse light of a first cycle, and the illumination portion is configured such that the detection light includes a second pulse light of a second cycle.

14. The laser processing apparatus of claim 13, wherein the laser processing apparatus is configured such that the second cycle is the same as the first cycle.

15. The laser processing apparatus of claim 14, wherein the laser processing apparatus is configured such that the second cycle is within a range of 50 kilohertz (kHz) to 200 kHz.

16. The laser processing apparatus of claim 14, wherein the laser processing apparatus is configured such that the second pulse light has a time delay with respect to the first pulse light, and the time delay is within a range of 5 μs.

17. The laser processing apparatus of claim 14, wherein the light detector includes an image sensor configured to detect the intensity of the reflected light.

18. The laser processing apparatus of claim 11, wherein the substrate includes a base substrate having a first surface and a second surface opposite to the first surface and a circuit layer formed on the first surface of the base substrate,
wherein the laser irradiation portion is configured such that the laser beam is irradiated onto the second surface of the base substrate, and
wherein the illumination portion is configured such that the detection light is irradiated onto the second surface of the base substrate.

19. The laser processing apparatus of claim 11, further comprising:
a driving portion configured to move the laser beam in a horizontal direction relative to the substrate.

20. A laser processing apparatus configured to laser process a substrate including a base substrate having a first surface and a second surface opposite to the first surface and a circuit layer formed on the first surface of the base substrate, the laser processing apparatus comprising:
a stage configured to support the substrate such that the first surface faces the stage;
a laser irradiation portion configured to focus a laser beam inside the substrate such that a laser damage layer is formed inside the substrate along a cutting line; and
a thermoreflectance measurement portion configured to irradiate a detection light to an adjacent region and to detect light reflected from the circuit layer in the adjacent region and to determine a location of splash defect in the adjacent region generated by the laser beam,
wherein the adjacent region is adjacent to a region where the laser beam is focused, and
wherein the thermoreflectance measurement portion is configured to irradiate the detection light such that the detection light is incident to the circuit layer through the second surface of the base substrate.
